(19) United States
(12) Patent Application Publication
(10) Pub. No.: US 2012/0279562 A1
(43) Pub. Date: Nov. 8, 2012

(54) BACK-SURFACE-FIELD TYPE OF HETEROJUNCTION SOLAR CELL AND A PRODUCTION METHOD THEREFOR

(75) Inventors: Su Mi Yang, Cheongwon-gun (KR); Sung Bong Roh, Chungju-si (KR); Seok Hyun Song, Yongin-si (KR)

(73) Assignee: HYUNDAI HEAVY INDUSTRIES CO., LTD., Ulsan (KR)

(21) Appl. No.: 13/516,931

(22) PCT Filed: Dec. 17, 2010
(86) PCT No.: PCT/KR2010/009063

§ 371 Date: Jun. 18, 2012

(30) Foreign Application Priority Data
Dec. 21, 2009 (KR) 10-2009-0127929

(51) Int. Cl. H01L 31/075; H01L 31/18

(52) U.S. Cl. 136/255; 438/87; 257/E31.047

(57) ABSTRACT

The back-surface-field type of heterojunction solar cell according to the present invention comprises a crystalline silicon substrate of a first conductivity type, a semiconductor layer of the first conductivity type provided in the upper stratum of the substrate, an anti-reflective film provided on the front surface of the substrate, an intrinsic layer provided on the rear surface of the substrate, amorphous semiconductor layers of the first conductivity type and amorphous semiconductor layers of the second conductivity type repeatedly disposed alternately on the intrinsic layer, and first-conductivity-type electrodes and second-conductivity-type electrodes which are respectively provided on the amorphous semiconductor layers of the first conductivity type and the amorphous semiconductor layers of the second conductivity type.

### TECHNICAL FIELD

The present disclosure relates to a back surface field hetero-junction solar cell and a manufacturing method thereof, and more particularly, to a back surface field hetero-junction solar cell and a manufacturing method thereof, which may maximize photoelectric transformation efficiency of a solar cell by grafting a hetero-junction solar cell and a back surface field solar cell.

### BACKGROUND ART

A solar cell is a core element of solar-light power generation, which directly transforms solar light into electricity, and it may be basically considered as a diode having a p-n junction. Solar light is transformed into electricity by a solar cell as follows. If solar light is incident to a p-n junction of a solar cell, an electron-hole pair is generated, and due to the electric field, electrons move to an n layer and holes move to a p layer, thereby generating photoelectromotive force between the p-n junctions. In this way, if a load or system is connected to both terminals of the solar cell, an electric power may flow to generate power.

A general solar cell is configured to have a front surface and a back electrode respectively at front and back surfaces of the solar cell. Since the front electrode is provided to the front surface which is a light-receiving surface, the light-receiving area decreases as much as the area of the front electrode. In order to solve the decrease of the light-receiving area, a back surface field solar cell has been proposed. The back surface field solar cell maximizes the light-receiving area of the front surface of the solar cell by providing a (+) electrode and a (−) electrode on a back surface of the solar cell.

The solar cell may be regarded as a diode with a p-n junction as described above, which has a junction structure of a p-type semiconductor layer and an n-type semiconductor layer. Generally, the p-type semiconductor layer is formed by implanting p-type impurity ions into a p-type substrate (or, vice versa) to make a p-n junction. As described above, in order to configure a p-n junction of a solar cell, a semiconductor layer into which impurity ions are implanted is inevitable.

However, charges generated by photoelectric transformation may be collected and recombined at interstitial sites or substitutional sites present in a semiconductor layer of the solar cell, while moving, which gives a bad influence on photoelectric transformation efficiency of the solar cell. In order to solve this problem, a so-called hetero-junction solar cell having an intrinsic layer between the p-type semiconductor layer and the n-type semiconductor layer has been proposed, and a rate of recombination of carriers may be lowered by using such a solar cell.

### DISCLOSURE

### Technical Problem

The present disclosure is directed to providing a back surface field hetero-junction solar cell and a manufacturing method thereof, which may maximize photoelectric transformation efficiency of a solar cell by grafting a hetero-junction solar cell and a back surface field solar cell.

### Technical Solution

In one general aspect, the present disclosure provides a back surface field hetero-junction solar cell, which includes: a first conductive crystalline silicon substrate; a first conductive semiconductor layer provided at an upper layer of the substrate; an anti-reflection film provided on a front surface of the substrate; an intrinsic layer provided on a back surface of the substrate; a first conductive amorphous semiconductor layer and a second conductive amorphous semiconductor layer arranged alternately on the intrinsic layer; and a first conductive electrode provided on the first conductive amorphous semiconductor layer and a second conductive electrode provided on the second conductive amorphous semiconductor layer

In another general aspect, the present disclosure also provides a manufacturing method of a back surface field hetero-junction solar cell, which includes: preparing a first conductive crystalline silicon substrate; forming a first conductive semiconductor layer at an upper layer of the substrate; forming an intrinsic layer on a back surface of the substrate; forming a first conductive amorphous semiconductor layer and a second conductive amorphous semiconductor layer to be arranged alternately on the intrinsic layer; and forming a first conductive electrode on the first conductive amorphous semiconductor layer and a second conductive electrode on the second conductive amorphous semiconductor layer.

The forming of a first conductive amorphous semiconductor layer and a second conductive amorphous semiconductor layer may further include: laminating an amorphous silicon layer on the intrinsic layer; forming a first conductive amorphous semiconductor layer by implanting first conductive impurity ions into a first region of the amorphous silicon layer through a shadow mask which exposes the first region of the amorphous silicon layer; forming a second conductive amorphous semiconductor layer by implanting second conductive impurity ions into a second region of the amorphous silicon layer through a shadow mask which exposes the second region of the amorphous silicon layer; and removing a portion of the amorphous silicon layer into which no impurity ion is implanted, between the first conductive amorphous semiconductor layer and the second conductive amorphous semiconductor layer.

The manufacturing method may further include forming seed layers on the first conductive amorphous semiconductor layer and the second conductive amorphous semiconductor layer before forming the first conductive electrode and the second conductive electrode, and the seed layer, the first conductive electrode and the second conductive electrode may be formed by means of electrolytic plating or electroless plating.

### Advantageous Effects

The back surface field hetero-junction solar cell and manufacturing method thereof according to the present disclosure has the following effects.

Since both a (+) electrode and a (−) electrode are provided on a back surface of a solar cell, the light-receiving area may be maximized. In addition, since an intrinsic layer into which no impurity ion is implanted is provided, a rate of recombination of carriers is minimized, which allows improving photoelectric transformation efficiency of the solar cell.

### DESCRIPTION OF DRAWINGS

FIG. 1 is a cross-sectional view of a back surface field hetero-junction solar cell according to an embodiment of the present disclosure; and

FIGS. 2a to 2e are cross-sectional views for illustrating a manufacturing method of the back surface field hetero-junction solar cell according to an embodiment of the present disclosure.

### BEST MODE

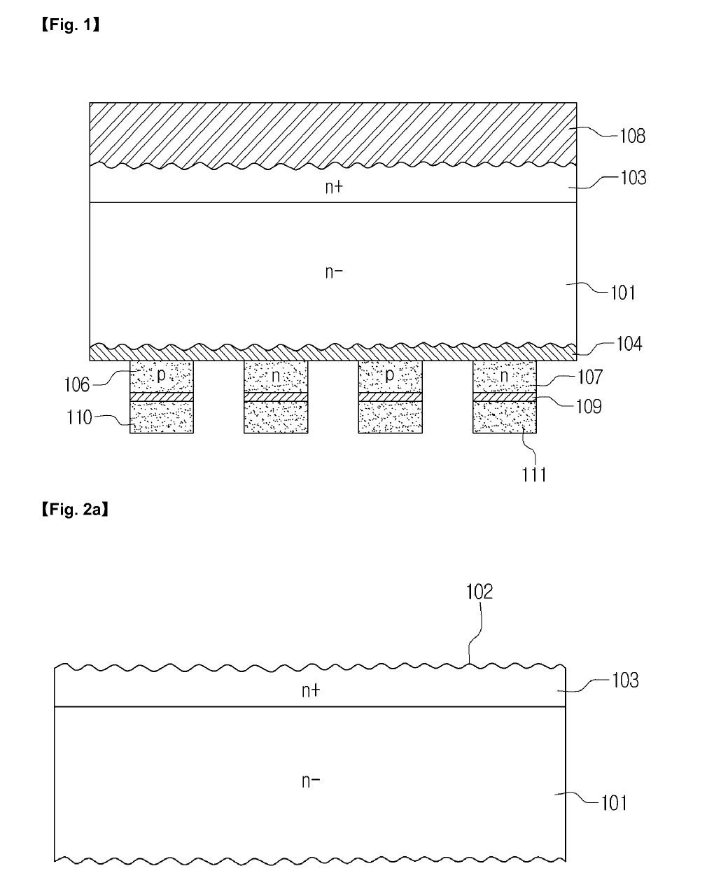

Hereinafter, a back surface field hetero-junction solar cell and a manufacturing method thereof according to an embodiment of the present disclosure will be described with reference to the accompanying drawings. FIG. 1 is a cross-sectional view of a back surface field hetero-junction solar cell according to an embodiment of the present disclosure.

As shown in FIG. 1, a back surface field hetero-junction solar cell according to an embodiment of the present disclosure includes a first conductive crystalline silicon substrate 101. The first conductive type may be p-type or n-type, and the second conductive type is opposite to the first conductive type. The following description will be based on that the first conductive type is n-type and the second conductive type is p-type.

An intrinsic layer 104 made of amorphous silicon into which no impurity ion is implanted is provided on the back surface of the n-type substrate 101 (n-), and a p-type amorphous semiconductor layer 106 (p) and an n-type amorphous semiconductor layer 107 (n) are arranged alternately on the intrinsic layer 104. In addition, a p electrode 110 and an n electrode 111 connected to an external circuit are respectively provided on the p-type amorphous semiconductor layer 106 and the n-type amorphous semiconductor layer 107. Seed layers 109 may be further provided between the p-type amorphous semiconductor layer 106 and the p electrode 110 and between the n-type amorphous semiconductor layer 107 and the n electrode 111. The seed layers 109 play a role of reducing a contact resistance between the amorphous semiconductor layer and the electrode and reducing a specific resistance of the p electrode 110 and the n electrode 111. The p electrode 110 and the n electrode 111 may be made of copper (Cu), nickel (Ni), tin or the like, and the seed layers 109 may be made of aluminum (Al) or the like.

An n-type semiconductor layer 103 is provided at the upper portion of the n-type substrate 101. The n-type semiconductor layer 103 may be formed by implanting and diffusing n-type impurity ions into the upper portion of the substrate 101. In addition, an anti-reflection film 108 configured with a silicon nitride film is formed on the front surface of the substrate 101.

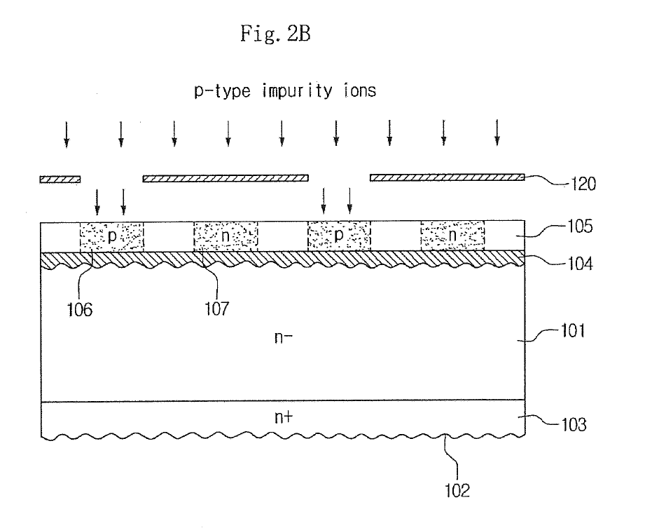

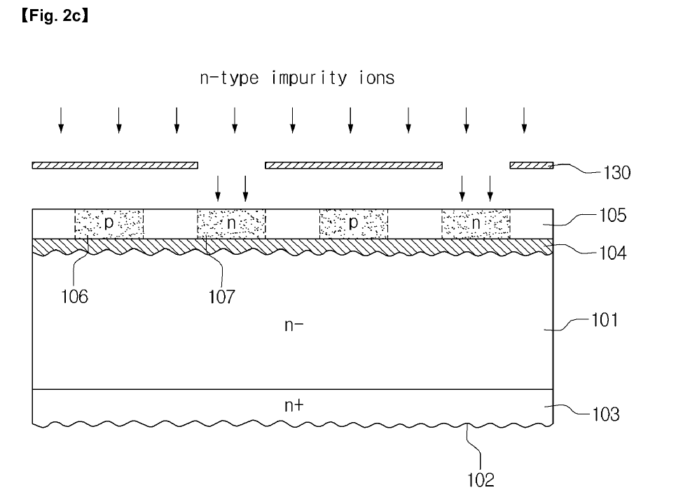

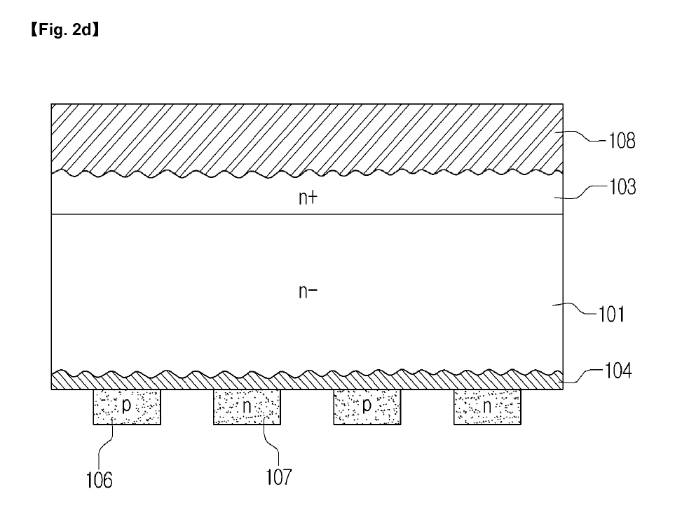

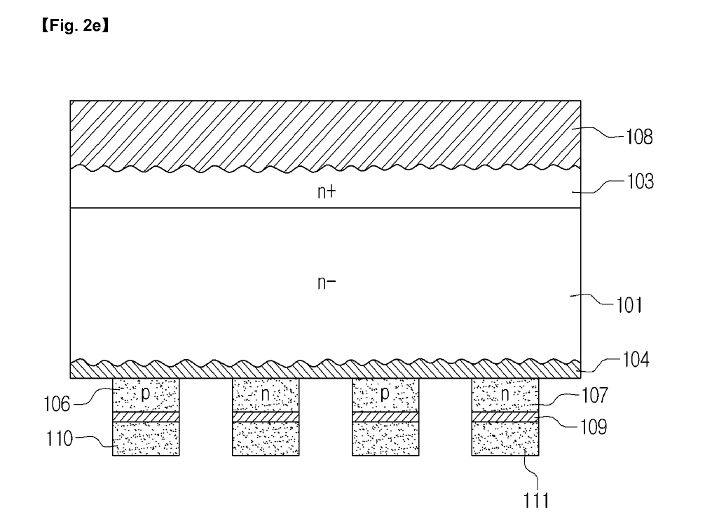

Next, a manufacturing method of the back surface field hetero-junction solar cell according to an embodiment of the present disclosure will be described. FIGS. 2a to 2e are cross-sectional views for illustrating the manufacturing method of the back surface field hetero-junction solar cell according to an embodiment of the present disclosure.

First, as shown in FIG. 2a, a first conductive, for example n-type, crystalline silicon substrate 101 is prepared. After that, a texturing process is performed so that unevenness 102 is formed at the surface of the substrate 101. The texturing process is used for maximizing light absorption and may be performed by using wet etching or dry etching such as reactive ion etching.

In a state where the texturing process is completed, a diffusing process is performed to form the n-type semiconductor layer 103 (n+) on the n-type substrate 101. In detail, the silicon substrate 101 is provided in a chamber, and gas (for example, POCI₃) containing n-type impurity ions is supplied into the chamber so that phosphorus (P) ions are diffused. By doing so, the n-type semiconductor layer 103 is formed at the upper layer of the substrate 101. In addition to the above method, n-type impurity ions may be implanted to the upper layer of the substrate 101 to form the n-type semiconductor layer 103.

In a state where the n-type semiconductor layer 103 is formed on the substrate 101, as shown in FIG. 2b, the intrinsic layer 104 made of amorphous silicon is laminated on the back surface of the substrate 101. The intrinsic layer 104 has no impurity ion implanted therein and may be formed by means of plasma enhanced chemical vapor deposition (PECVD).

In this state, the p-type amorphous semiconductor layer 106 (p) and the n-type amorphous semiconductor layer 107 (n) are formed on the intrinsic layer 104. In detail, first, an amorphous silicon layer 105 is laminated on the intrinsic layer 104. After that, a shadow mask 120 is located at a position spaced from the amorphous silicon layer 105 to selectively expose a portion of the amorphous silicon layer 105 where the p-type amorphous semiconductor layer 106 is to be formed, and then p-type impurity ions are implanted into the exposed portion of the amorphous silicon layer 105 to form the p-type amorphous semiconductor layer 106. Subsequently, as shown in FIG. 2c, a shadow mask 130 is located at a position spaced apart from the amorphous silicon layer 105 to expose a portion of the amorphous silicon layer 105 where the n-type amorphous semiconductor layer 107 is to be formed, and then n-type impurity ions are implanted to the exposed portion of the amorphous silicon layer 105 to form the n-type amorphous semiconductor layer 107. In this way, the p-type amorphous semiconductor layer 106 and the n-type amorphous semiconductor layer 107 may be formed to be alternately arranged. Finally, if the amorphous silicon layer 105 where no impurity ion is implanted is removed between the p-type amorphous semiconductor layer 106 and the n-type amorphous semiconductor layer 107, the process of forming the p-type amorphous semiconductor layer 106 and the n-type amorphous semiconductor layer 107 is completed.

In a state where the p-type amorphous semiconductor layer 106 and the n-type amorphous semiconductor layer 107 are formed, as shown in FIG. 2d, an anti-reflection film 108 is formed on the front surface of the substrate 101. After that, a plating mask is formed on the back surface of the substrate 101. The plating mask selectively exposes regions where the p-type amorphous semiconductor layer 106 and the n-type amorphous semiconductor layer 107 are provided.

In this state, as shown in FIG. 2e, seed layers 109 are formed on the p-type amorphous semiconductor layer 106 and the n-type amorphous semiconductor layer 107 by means of electrolytic plating or electroless plating. Subsequently, if a p electrode 110 and an n electrode 111 are formed on the seed layers 109 by means of plating, the manufacturing method of a back surface field hetero-junction solar cell according to an embodiment of the present disclosure is completed. The seed layer 109 and the electrode may also be formed by means of physical vapor deposition instead of plating. In other words, a material of the seed layer 109 and an electrode material may be successively laminated on the back surface of the substrate 101 by means of physical vapor deposition such as sputtering and then selectively patterned to form the seed layers 109, the p electrode 110 and the n electrode 111.

### INDUSTRIAL APPLICABILITY

Since both a (+) electrode and a (−) electrode are provided on a back surface of a solar cell, the light-receiving area may be maximized. In addition, since an intrinsic layer into which no impurity ion is implanted is provided, a rate of recombination of carriers is minimized, which allows improving photoelectric transformation efficiency of the solar cell.

1. A back surface field hetero-junction solar cell, comprising:
a first conductive crystalline silicon substrate;
a first conductive semiconductor layer provided at an upper layer of the substrate;
an anti-reflection film provided on a front surface of the substrate;
an intrinsic layer provided on a back surface of the substrate;
a first conductive amorphous semiconductor layer and a second conductive amorphous semiconductor layer arranged alternately on the intrinsic layer; and
a first conductive electrode provided on the first conductive amorphous semiconductor layer and a second conductive electrode provided on the second conductive amorphous semiconductor layer.

2. The back surface field hetero-junction solar cell according to claim 1, further comprising seed layers respectively between the first conductive amorphous semiconductor layer and the first conductive electrode and between the second conductive amorphous semiconductor layer and the second conductive electrode.

3. A manufacturing method of a back surface field hetero-junction solar cell, the method comprising:
preparing a first conductive crystalline silicon substrate;
forming a first conductive semiconductor layer at an upper layer of the substrate;
forming an intrinsic layer on a back surface of the substrate;
forming a first conductive amorphous semiconductor layer and a second conductive amorphous semiconductor layer to be arranged alternately on the intrinsic layer; and
forming a first conductive electrode on the first conductive amorphous semiconductor layer and a second conductive electrode on the second conductive amorphous semiconductor layer.

4. The manufacturing method of a back surface field hetero-junction solar cell according to claim 3, wherein said forming of the first conductive amorphous semiconductor layer and the second conductive amorphous semiconductor layer includes:
forming an amorphous silicon layer on the intrinsic layer;
forming the first conductive amorphous semiconductor layer by implanting first conductive impurity ions into a first region of the amorphous silicon layer through a shadow mask which exposes the first region of the amorphous silicon layer;
forming the second conductive amorphous semiconductor layer by implanting second conductive impurity ions into a second region of the amorphous silicon layer through a shadow mask which exposes the second region of the amorphous silicon layer; and
removing a portion of the amorphous silicon layer into which no impurity ion is implanted, between the first conductive amorphous semiconductor layer and the second conductive amorphous semiconductor layer.

5. The manufacturing method of a back surface field hetero-junction solar cell according to claim 3, further comprising:
forming seed layers on the first conductive amorphous semiconductor layer and the second conductive amorphous semiconductor layer before forming the first conductive electrode and the second conductive electrode.

6. The manufacturing method of a back surface field hetero-junction solar cell according to claim 5, wherein the seed layer, the first conductive electrode and the second conductive electrode are formed by means of electrolytic plating or electroless plating.
